(19) United States
(12) Patent Application Publication
(10) Pub. No.: US 2026/0150391 A1
(43) Pub. Date: May 28, 2026

(54) BACKSIDE CONTACT FOR VERTICAL FET

(71) Applicant: INTERNATIONAL BUSINESS MACHINES CORPORATION, ARMONK, NY (US)

(72) Inventors: Min Gyu Sung, Latham, NY (US); Ruilong Xie, Niskayuna, NY (US); Tao Li, Slingerlands, NY (US); Kisik Choi, Watervliet, NY (US); Nicolas Jean Loubet, Guilderland, NY (US)

(21) Appl. No.: 18/961,830

(22) Filed: Nov. 27, 2024

(51) Int. Cl. H10D 84/83; H10D 30/01; H10D 30/43; H10D 30/63; H10D 62/10

(52) U.S. Cl. CPC H10D 84/837; H10D 30/014; H10D 30/43; H10D 30/63; H10D 62/121; H10D 62/126; H10D 84/834

(57) ABSTRACT

A microelectronic structure includes a first vertical field-effect-transistor (FET) and a second vertical FET. The first vertical FET is adjacent to the second vertical FET and the first vertical FET includes a top source/drain. A lateral extending contact that is located on top of the top source/drain and the lateral extending contact extends towards the second vertical FET. A backside contact located between the first vertical FET and the second vertical FET. The backside contact is connected to a backside surface of the lateral extending contact. The backside contact has a first critical dimension located at the backside surface of the backside contact. The backside contact has a second critical dimension located at the backside surface of the lateral extending contact. The first critical dimension is greater than the second critical dimension.

### BACKGROUND

The present invention generally relates to the field of microelectronics, and more particularly to forming backside contacts in vertical FETs.

Vertical FET technology has shown issues when scaling down such that as the devices becoming smaller and closer together, they are interfering with each other. With the number of vertical FETs increase the amount of space available to form the necessary contacts is decreasing.

### BRIEF SUMMARY

Additional aspects and/or advantages will be set forth in part in the description which follows and, in part, will be apparent from the description, or may be learned by practice of the invention.

A microelectronic structure includes a first vertical field-effect-transistor (FET) and a second vertical FET. The first vertical FET is adjacent to the second vertical FET and the first vertical FET includes a top source/drain. A lateral extending contact that is located on top of the top source/drain and the lateral extending contact extends towards the second vertical FET. A backside contact located between the first vertical FET and the second vertical FET. The backside contact is connected to a backside surface of the lateral extending contact. The backside contact has a first critical dimension located at the backside surface of the backside contact. The backside contact has a second critical dimension located at the backside surface of the lateral extending contact. The first critical dimension is greater than the second critical dimension.

A microelectronic structure includes a first vertical field-effect-transistor (FET) and a second vertical FET. The first vertical FET is adjacent to the second vertical FET. The first vertical FET includes a first top source/drain and a first fin and the second vertical FET includes a second top source/drain and second fin. A gate located between the first fin and the second fin. A lateral extending contact that is located on top of the top source/drain. The lateral extending contact extends towards the second vertical FET and the lateral extending contact is located above the gate. A backside contact located between the first vertical FET and the second vertical FET and the backside contact extends through the gate. The backside contact is connected to a backside surface of the lateral extending contact. The backside contact has a first critical dimension located at the backside surface of the backside contact and the backside contact has a second critical dimension located at the backside surface of the lateral extending contact. The first critical dimension is greater than the second critical dimension.

A method includes the steps of forming a first vertical field-effect-transistor and a second vertical FET. The first vertical FET is adjacent to the second vertical FET and the first vertical FET includes a top source/drain. Forming a lateral extending contact that is located on top of the top source/drain and the lateral extending contact extends towards the second vertical FET. Forming a backside contact located between the first vertical FET and the second vertical FET. The backside contact is connected to a backside surface of the lateral extending contact. The backside contact has a first critical dimension located at the backside surface of the backside contact. The backside contact has a second critical dimension located at the backside surface of the lateral extending contact. The first critical dimension is greater than the second critical dimension.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of vertical FETs, in accordance with the embodiment of the present invention.

FIG. 2 illustrates a cross-section X of the vertical FET after frontside processing of the vertical FET, in accordance with the embodiment of the present invention.

FIG. 3 illustrates a cross-section X of the vertical FET after initial backside processing of the vertical FET, in accordance with the embodiment of the present invention.

FIG. 4 illustrates a cross-section X of the vertical FET after increasing the height of the oxide layer, in accordance with the embodiment of the present invention.

FIG. 5 illustrates a cross-section X of the vertical FET after formation of backside vias, in accordance with the embodiment of the present invention.

FIG. 6 illustrates a cross-section X of the vertical FET after formation of a first and second backside metal lines and formation of the backside interlayer dielectric layer, in accordance with the embodiment of the present invention.

FIG. 7 illustrates a cross-section X of the vertical FET after formation of a backside contact via trench, in accordance with the embodiment of the present invention.

FIG. 8 illustrates a cross-section X of the vertical FET after formation of a backside contact liner and backside contact via, in accordance with the embodiment of the present invention.

FIG. 9 illustrates a cross-section X of the vertical FET after formation of a backside connector trench, in accordance with the embodiment of the present invention.

FIG. 10 illustrates a cross-section X of the vertical FET after formation of a backside connector and formation of a backside interconnect, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an “example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards a backside contact for a vertical field-effect-transistor (FET). Backside processing allows for the separation of components between the frontside region and the backside region of the vertical FET. A backside contact is formed in the gate cut region between two adjacent vertical FETs, where the backside contact is connected to a lateral frontside contact that extends laterally off one of the source/drains. The backside contact has a first critical dimension at its backside surface and a second critical dimension at the lateral frontside contact. The second critical dimension is smaller than the first critical dimension. The backside contact extends between the metal rails/lines/contacts for each of the adjacent vertical FETs. Furthermore, the backside contact separates the gate region located between the two adjacent vertical FETs into separate gates.

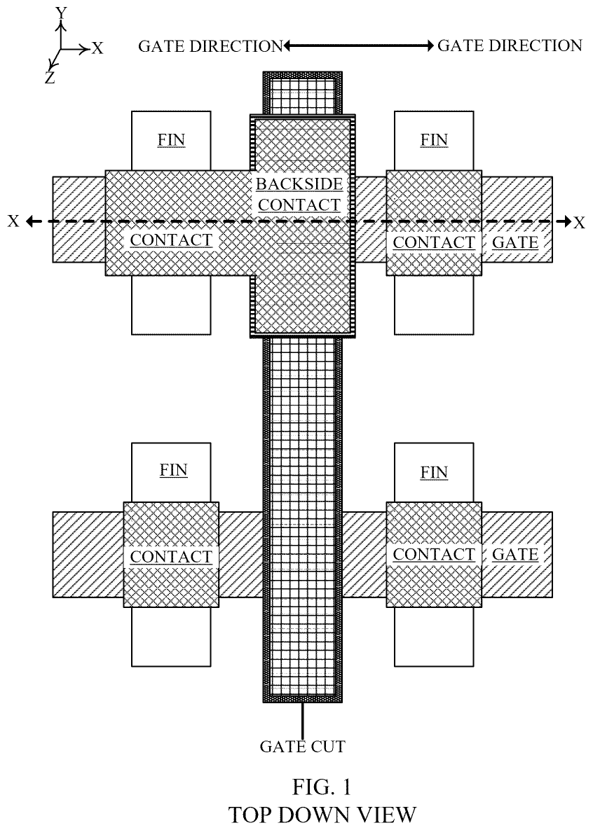

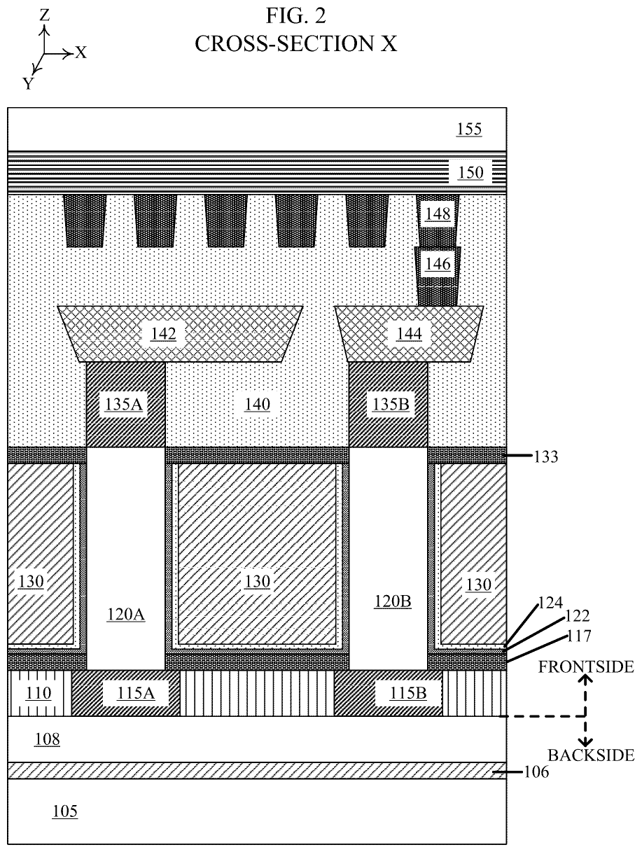

FIG. 1 illustrates a top-down view of a plurality of vertical FETs, in accordance with the embodiment of the present invention. Cross-section X extends parallel to the gate direction and extends through adjacent vertical FETs. FIG. 1 illustrates the different components on a board scale and reference number will be assigned to the components illustrated in FIGS. 2-10 as described below.

Referring now to FIG. 2, a structure is shown during an intermediate step of a method of fabricating vertical field-effect-transistors (FET) or a FinFET structure after frontside processing, according to an embodiment of the invention.

FIG. 2 illustrates cross-section X that is parallel to the gate direction and passes through adjacent vertical FETs or adjacent FinFETs. The adjacent vertical FETs include a first substrate 105, an etch stop 106, a second substrate 108, an oxide layer 110, a first lower source/drain 115A, a second lower source/drain 115B, a first fin 120A, a second fin 120B, a bottom spacer 117, a gate 122, 124, 130, a top spacer 133, a first top source/drain 135A, a second top source/drain 135B, a frontside interlayer dielectric layer 140, a lateral frontside contact 142, a frontside contact 144, frontside connecting via 146, a plurality of frontside metal lines 148, frontside interconnect 150, and a carrier wafer 155.

The first substrate 105 and the second substrate 108 can be, for example, a material including, but not necessarily limited to, silicon (Si), silicon germanium (SiGe), Si:C (carbon doped silicon), carbon doped silicon germanium (SiGe: C), III-V, II-V compound semiconductor or another like semiconductor. In addition, multiple layers of semiconductor materials can be used as the semiconductor material of the first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein.

The first fin 120A is located between the first lower source/drain 115A and the first top source/drain 135A. The second fin 120B is located between the second lower source/drain 115B and the second top source/drain 135B. A gate 122, 124, 130 is located on the sides of the first and second fins 120A, 120B, where the gate 122, 124, 130 extends in the gate direction as illustrated in FIGS. 1 and 2. The gate 122, 124, 130 includes a gate dielectric liner 122, a work function layer 124, and a fill layer 130. The gate dielectric liner 122 can be comprised of, for example, high-k dielectric like HfO₂, ZrO₂, HfLₐOₓ, etc. The work function layer 124 can be comprised of, for example, TiN, TiAlC, TiC, etc. The fill layer 130 can be comprised of for example, a conductive metal, like Tungsten (W).

The first and second lower source/drains 115A, 115B and the first and second top source/drains 135A, 135B can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

The lateral frontside contact 142 and the frontside contact 144 are located on one of the top of the first and second top source/drains 135A, 135B, respectively. Specifically, the lateral frontside contact 142 is located on top of the first top source/drain 135A, where the lateral frontside contact 142 extends laterally towards the adjacent vertical FET. The lateral frontside contact 142 extends into the gate cut region located between the adjacent vertical FETs. The frontside contact 144 is located on top of the second top source/drain 135B. The frontside interlayer dielectric layer 140 surrounds the first and second top source/drains 135A, 135B, the lateral frontside contact 142, and the frontside contact 144. A frontside connecting via 146 is formed in the frontside interlayer dielectric layer 140, where the frontside connecting via 146 is in contact with frontside contact 144. A plurality of frontside metal lines 148 are located in the frontside interlayer dielectric layer 140. The plurality of frontside metal lines 148 can be, for example, power lines (VSS, VDD, ground), signal lines, clock lines, or another type of metal line. The frontside interconnect 150 is located on top of the frontside interlayer dielectric layer 140 and on top of the plurality of frontside metal lines 148. The frontside interconnect 150 can be comprised of one or more layers/levels, one or more vias, and one or more metal lines. For simplicity, the frontside interconnect 150 is illustrated as one layer. Furthermore, frontside connecting via 146, and the plurality of frontside metal lines 148 can be part of the frontside interconnect 150. Carrier wafer 155 is located on top of the frontside interconnect 150. The carrier wafer 155 allows for the vertical FETs to be flipped over for backside processing of the backside region of the vertical FETs.

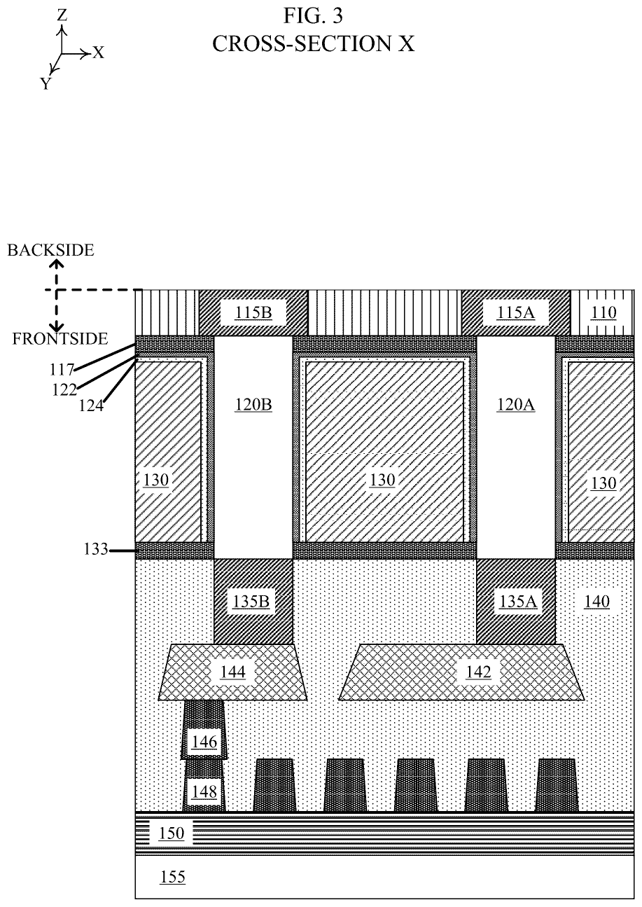

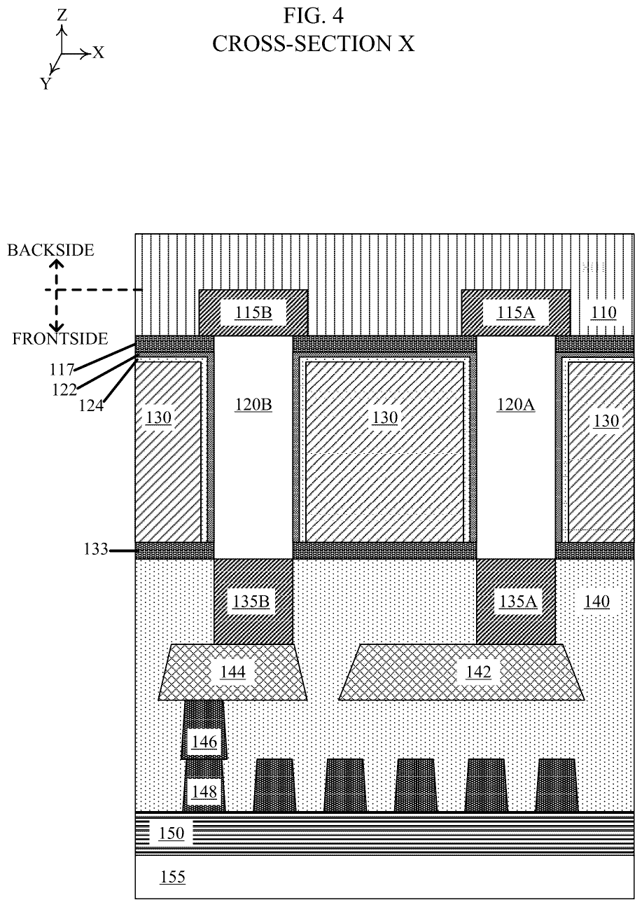

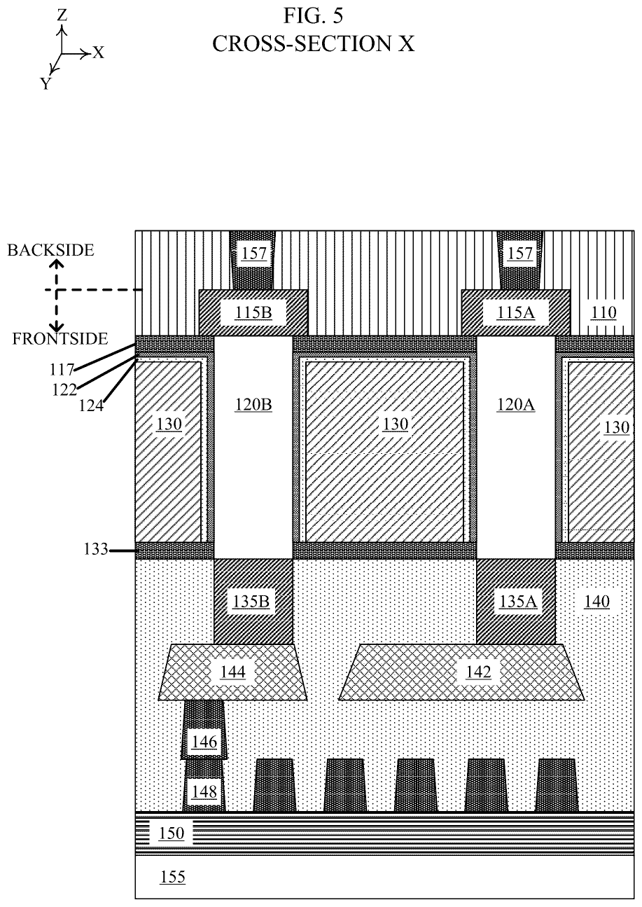

FIG. 3 illustrates the processing stage after flipping the wafer/chip over and initial backside processing. The first substrate 105, the etch stop 106, and the second substrate 108 are removed. The removal of these layers exposes a backside surface of the first and second lower source/drains 115A, 115B, and exposes a backside surface of the oxide layer 110. FIG. 4 illustrates the processing stage after increasing the height of the oxide layer 110. Additional oxide material is added to increase the height of the oxide layer 110, such that the oxide layer 110 extends over the backside surface of the first and second lower source/drains 115A, 115B. FIG. 5 illustrates the processing stage after the formation of backside vias 157. A lithography layer (not shown) is formed on oxide layer 110. The lithography layer (not shown) and the oxide layer 110 are patterned to form a plurality of trenches (not shown) within the oxide layer 110. Each of the trenches (not shown) exposes a backside surface of an underlying component, such as, the first and second lower source/drain 115A, 115B, respectively. A metallization process is utilized to fill these trenches (not shown) with a conductive metal to form the backside vias 157. Excess metal and the lithography layer (not shown) are removed by, for example, a chemical mechanical planarization (CMP) process. Separate backside vias 157 are connected to each of the first and second lower source/drains 115A, 155B. The backside vias 157 are each vertically aligned with one of the lower source/drains (first or second lower source/drains 115A, 155B), one of the fins (first or second fin 120A, 120B), and the top source/drain (first or second top source/drain 135A, 135B).

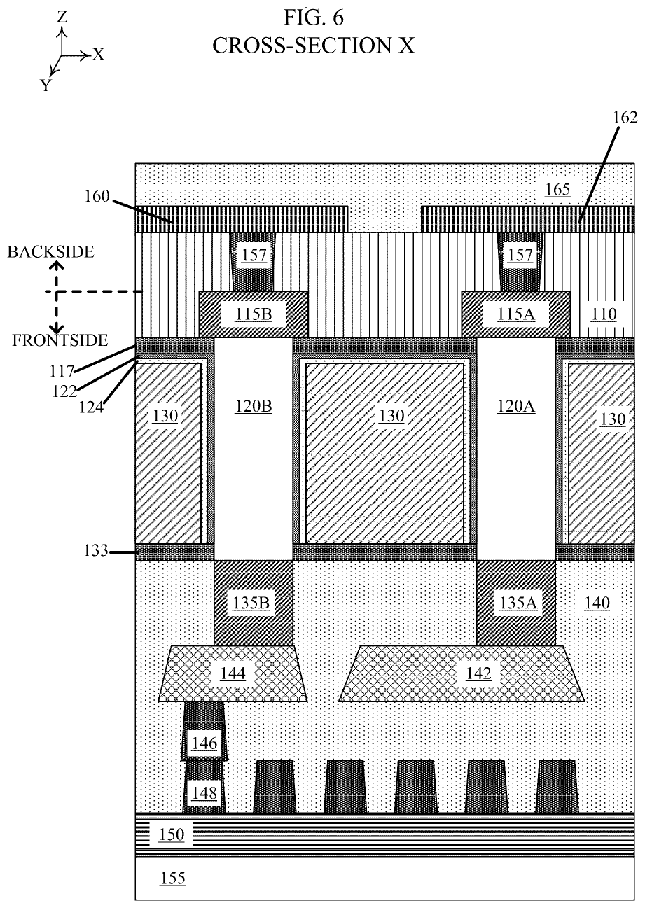

FIG. 6 illustrates the processing stage after formation of first and second backside metal lines 160, 162 and formation of the backside interlayer dielectric layer 165. A metal layer (not shown) is formed on top of the oxide layer 110 and on top of the backside vias 157. The metal layer (not shown) is etched/patterned to form at least a first metal line 160 and a second metal line 162. The first and second metal lines 160, 162 can be, for example, power lines (VSS, VDD, or ground), signal lines, clock lines, or another type of metal line. A backside interlayer dielectric layer 165 is formed on top of and around the first and second metal line 160, 162. The backside interlayer dielectric layer 165 can be comprised of the same material as the oxide layer 110 or the backside layer 165 can be comprised of a different material than the oxide layer 110.

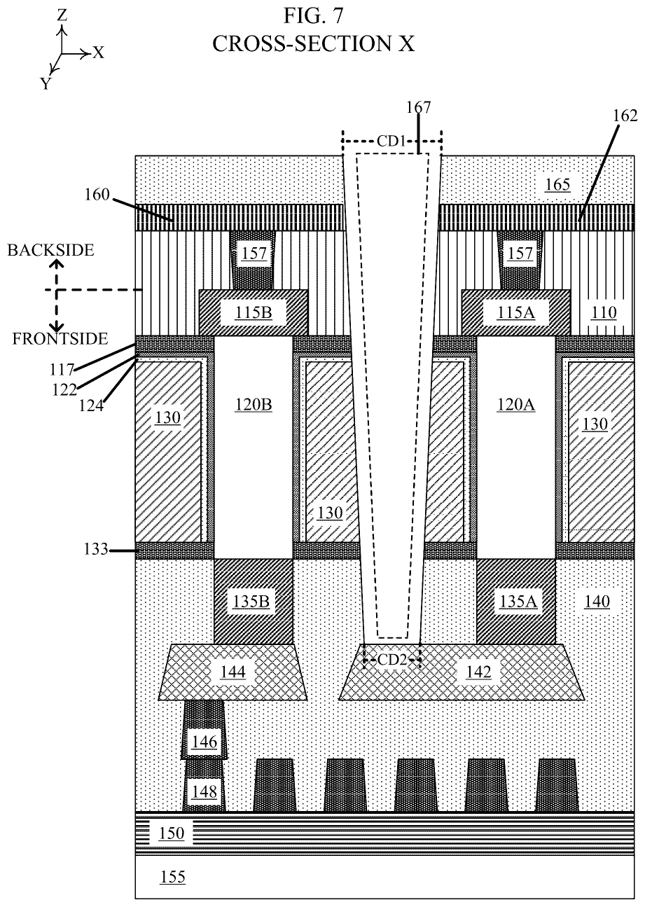

FIG. 7 illustrates the processing stage after formation of a backside contact via trench 167. A lithography layer (not shown) is formed on top of the backside interlayer dielectric layer 165. The lithography layer (not shown) and the underlying layers are etched/patterned to form the backside contact via trench 167. The lithography layer (not shown) is removed. The backside contact via trench 167 is located between the first fin 120A and the second fin 120B. The backside contact via trench 167 extends into the frontside region, specifically, the backside contact via trench 167 extends to the lateral frontside contact 142. The backside contact via trench 167 exposes a backside surface of the lateral frontside contact 142. The backside contact via trench 167 has tapered sidewalls, such that the opening of the backside contact via trench 167 has a first critical dimension and the bottom boundary of the backside contact via trench 167 has a second critical dimension. Since the sidewalls of the backside contact via trench 167 are tapered which causes the second critical dimension to be smaller than the first critical dimension.

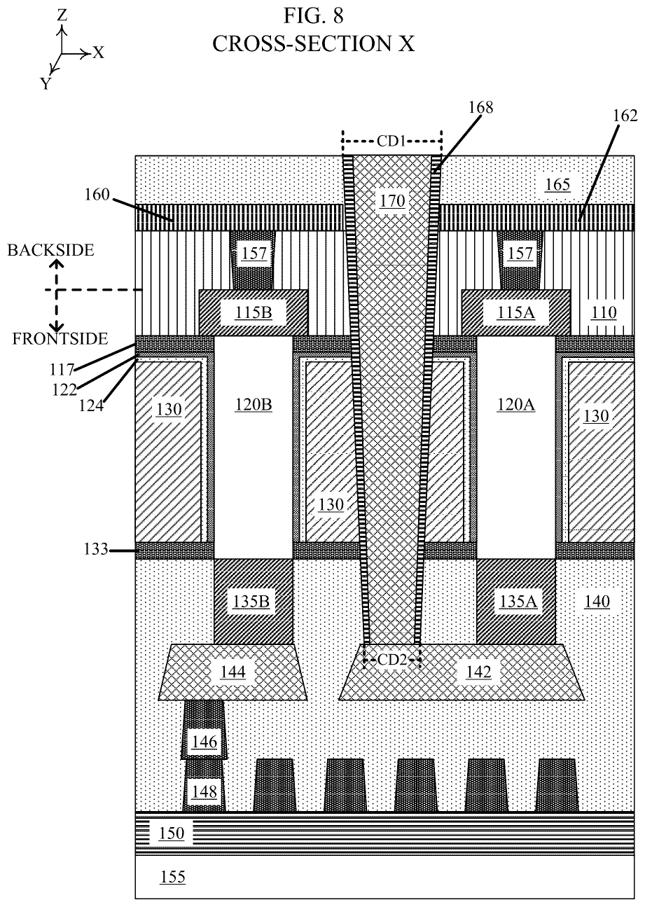

FIG. 8 illustrates the processing stage after formation of a backside contact liner 168 and backside contact via 170. The backside contact liner 168 is formed along the boundaries of backside contact via trench 167. The backside contact liner 168 is etched back to expose the backside surface of the lateral frontside contact 142, such that, the backside contact liner 168 only remains along the tapered sidewalls of the backside contact via trench 167. A metallization process is utilized to fill the rest of the backside contact via trench 167 with a conductive metal to form the backside contact via 170. The backside contact via 170 is in contact with a backside surface of the lateral frontside contact 142. The depth or vertical dimension of the backside contact 170 is larger than the combined depth or vertical dimension of the first and second backside metal liner 160, 162, the backside connecting vias 157, the first and second lower source/drain 115A, 115B, the first and second fins 120A, 120B, and the first and second top source/drains 135A, 135B.

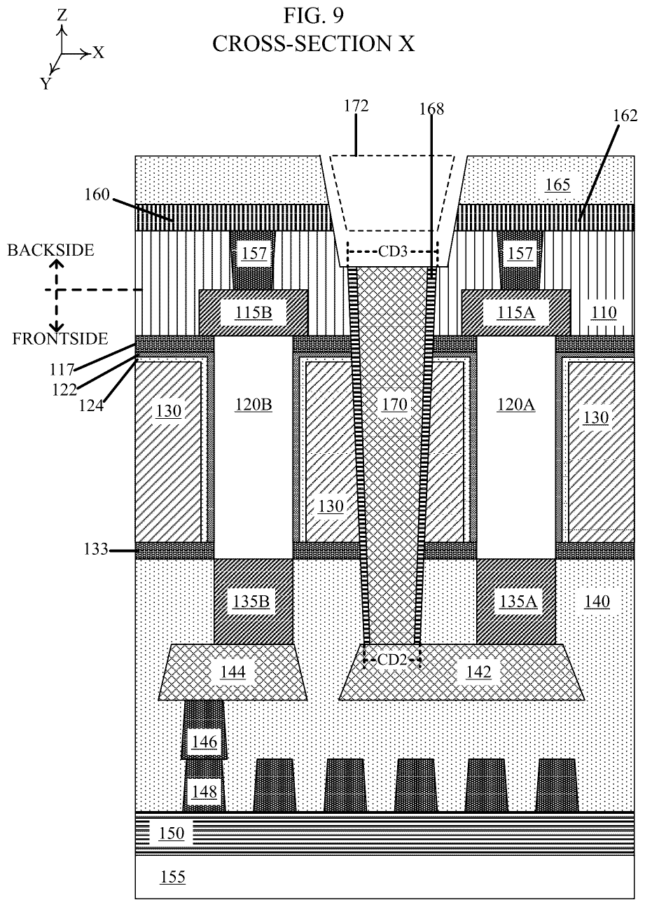

FIG. 9 illustrates the processing stage after the formation of a backside connector trench 172. A lithography layer (not shown) is formed on top of the backside interlayer dielectric layer 165. The lithography layer (not shown), the backside interlayer dielectric layer 165, the backside contact liner 168, the backside contact via 170, and the oxide layer 110 are etched/patterned to form the backside connector trench 172. Furthermore, the formation of the backside connector trench 172 can etch portions of the first and second metal lines 160, 162. The lithography layer (not shown) is removed. The backside connector trench 172 decreases the height/depth/vertical dimension of the backside contact liner 168, and the backside contact via 170, such that the top surface of both the backside contact liner 168, and the backside contact via 170 is located below a bottom surface of the first and second metal lines 160, 162. Backside contact liner 168 and the backside contact via 170 have a combined third critical dimension which is located at the bottom of the backside connector trench 172. Backside contact liner 168 and the backside contact via 170 have a combined second critical dimension located at the backside surface of the lateral frontside contact 142. The combined second critical dimension of the backside contact liner 168 and the backside contact via 170 is equal to the second critical dimension of the backside contact via trench 167. The combined third critical dimension is larger than the combined second critical dimension. The bottom boundary of the backside connector trench 172 is larger than the combined third critical dimension.

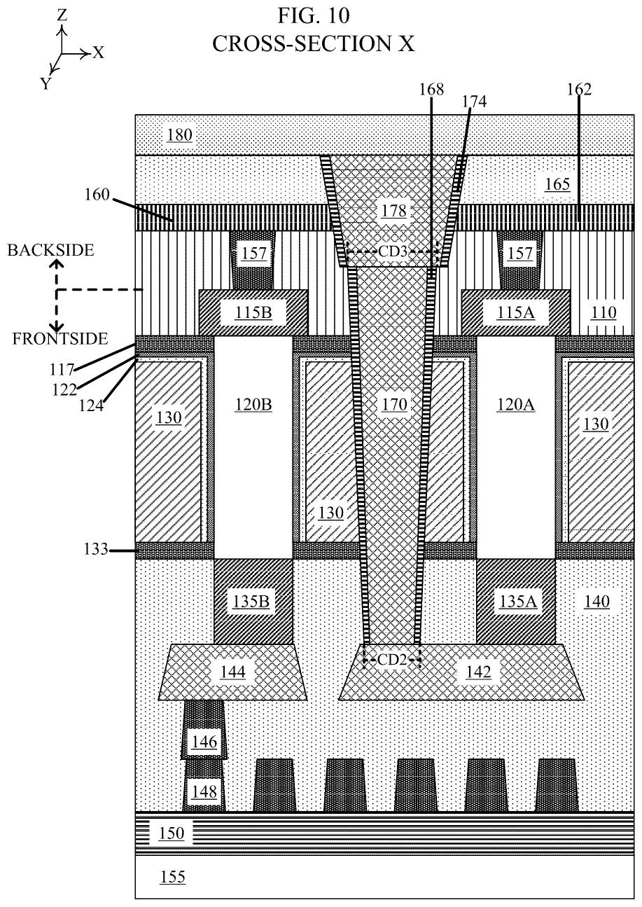

FIG. 10 illustrates the processing stage after the formation of the backside connector 178 and the formation of a backside interconnect 180. The backside connector trench 172 is lined with a backside connector liner 174. A metallization process is utilized to fill the rest of the backside connector trench 172 with a conductive metal to form the backside connector 178. The backside connector 178 can be a metal line, a via, or a lateral metal connector. The backside connector liner 174 isolates the backside connector 178 from the first and second metal lines 160, 162. A backside interconnect 180 is formed on top of the backside interlayer dielectric layer 165, the backside connector liner 174, and the backside connector 178. The backside interconnect 180 can be comprised of one or more layers/level, one or more vias, and/or one or more metal lines. The backside interconnect 180 can be, for example, a backside-power-distribution-network (BSPDN).

A microelectronic structure includes a first vertical field-effect-transistor (FET) and a second vertical FET. The first vertical FET is adjacent to the second vertical FET and the first vertical FET includes a top source/drain 135A. A lateral extending contact 142 that is located on top of the top source/drain 135A and the lateral extending contact 142 extends towards the second vertical FET. A backside contact 168, 170 located between the first vertical FET and the second vertical FET. The backside contact 168, 170 is connected to a backside surface of the lateral extending contact 142. The backside contact 168, 170 has a first critical dimension (CD3) located at the backside surface of the backside contact 168, 170. The backside contact 168, 170 has a second critical dimension (CD2) located at the backside surface of the lateral extending contact 142. The first critical dimension (CD3) is greater than the second critical dimension (CD2).

The first vertical FET further includes a bottom source/drain 115A, and a vertical fin 120A. The top source/drain 135A, the vertical fin 120A, and the bottom source/drain 115A combine to have a first combined vertical dimension. The backside contact 168, 170 has a backside vertical dimension and the backside vertical dimension is greater than the first combined vertical dimension.

A connecting via 157 located on the backside surface of the bottom source/drain 115A and a metal line 162 connected to the connecting via 157. The top source/drain 135A, the vertical fin 120A, the bottom source/drain 115A, the connecting via 157, and the metal line 162 combine to have a second combined vertical dimension. The second combined vertical dimension is greater than the backside vertical dimension.

A microelectronic structure includes a first vertical field-effect-transistor (FET) and a second vertical FET. The first vertical FET is adjacent to the second vertical FET. The first vertical FET includes a first top source/drain 135A and a first fin 120A and the second vertical FET includes a second top source/drain 135B and second fin 120B. A gate 122, 124, 130 located between the first fin 120A and the second fin 120B. A lateral extending contact 142 that is located on top of the top source/drain 1325A. The lateral extending contact 142 extends towards the second vertical FET and the lateral extending contact 142 is located above the gate 122, 124, 130. A backside contact 168, 170 located between the first vertical FET and the second vertical FET and the backside contact 168, 170 extends through the gate. The backside contact 168, 170 is connected to a backside surface of the lateral extending contact 142. The backside contact 168, 170 has a first critical dimension (CD3) located at the backside surface of the backside contact 168, 170 and the backside contact 168, 170 has a second critical dimension (CD2) located at the backside surface of the lateral extending contact 142. The first critical dimension is greater than the second critical dimension.

The first vertical FET further includes a first bottom source/drain 115A, and the second vertical FET includes a second bottom source/drain 115B. The first top source/drain 135A, the first fin 120A, and the first bottom source/drain 115A combine to have a first combined vertical dimension. The backside contact 168, 170 has a backside vertical dimension and the backside vertical dimension is greater than the first combined vertical dimension.

A first connecting via 157 located on the backside surface of the first bottom source/drain 115A and a second connecting via 157 located on the backside surface of the second bottom source/drain 115B. A first metal line 162 connected to the first connecting via 157 and a second metal line 160 connected to the second connecting via 157. The first top source/drain 135A, the first fin 120A, the first bottom source/drain 115A, the first connecting via 157, and the first metal line 162 combine to have a second combined vertical dimension. The second combined vertical dimension is greater than the backside vertical dimension.

A connector 174, 178 located on the backside surface of the backside contact 168, 170 and the connector 174, 178 is located between the first metal line 162 and the second metal line 160. The connector 174, 178 has a vertical dimension, and the backside vertical dimension and the vertical dimension of the connector 174, 178 form a combined vertical dimension. The combined vertical dimension of the connector 174, 178 and the backside contact 168, 170 is greater than the second combined vertical dimension.

A method includes the steps of forming a first vertical field-effect-transistor (FET) and a second vertical FET. The first vertical FET is adjacent to the second vertical FET and the first vertical FET includes a top source/drain 135A. Forming a lateral extending contact 142 that is located on top of the top source/drain 135A and the lateral extending contact 142 extends towards the second vertical FET. Forming a backside contact 168, 170 located between the first vertical FET and the second vertical FET. The backside contact 168, 170 is connected to a backside surface of the lateral extending contact 142. The backside contact 168, 170 has a first critical dimension (CD3) located at the backside surface of the backside contact 168, 170. The backside contact 168, 170 has a second critical dimension (CD2) located at the backside surface of the lateral extending contact 142. The first critical dimension (CD3) is greater than the second critical dimension (CD2).

The first vertical FET further includes a bottom source/drain 115A, and a vertical fin 120A. The top source/drain 135A, the vertical fin 120A, and the bottom source/drain 115A combine to have a first combined vertical dimension. The backside contact 168, 170 has a backside vertical dimension and the backside vertical dimension is greater than the first combined vertical dimension.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of one or more embodiment, the practical application or technical improvement over technologies found in the marketplace, or to enable others of ordinary skill in the art to understand the embodiments disclosed herein.

What is claimed is:

1. A microelectronic structure comprising:
a first vertical field-effect-transistor (FET) and a second vertical FET, wherein the first vertical FET is adjacent to the second vertical FET, wherein the first vertical FET includes a top source/drain;
a lateral extending contact that is located on top of the top source/drain, wherein the lateral extending contact extends towards the second vertical FET; and
a backside contact located between the first vertical FET and the second vertical FET, wherein the backside contact is connected to a backside surface of the lateral extending contact, wherein the backside contact has a first critical dimension located at the backside surface of the backside contact, wherein the backside contact has a second critical dimension located at the backside surface of the lateral extending contact, wherein the first critical dimension is greater than the second critical dimension.

2. The microelectronic structure of claim 1, wherein the first vertical FET further includes a bottom source/drain, and a vertical fin.

3. The microelectronic structure of claim 2, wherein the top source/drain, the vertical fin, and the bottom source/drain combine to have a first combined vertical dimension.

4. The microelectronic structure of claim 3, wherein the backside contact has a backside vertical dimension, wherein the backside vertical dimension is greater than the first combined vertical dimension.

5. The microelectronic structure of claim 4, further comprises:
a connecting via located on the backside surface of the bottom source/drain; and
a metal line connected to the connecting via.

6. The microelectronic structure of claim 5, wherein the top source/drain, the vertical fin, the bottom source/drain, the connecting via, and the metal line combine to have a second combined vertical dimension.

7. The microelectronic structure of claim 6, wherein the second combined vertical dimension is greater than the backside vertical dimension.

8. A microelectronic structure comprising:
a first vertical field-effect-transistor (FET) and a second vertical FET, wherein the first vertical FET is adjacent to the second vertical FET, wherein the first vertical FET includes a first top source/drain and a first fin, wherein the second vertical FET includes a second top source/drain and second fin;
a gate located between the first fin and the second fin;
a lateral extending contact that is located on top of the top source/drain, wherein the lateral extending contact extends towards the second vertical FET, wherein the lateral extending contact is located above the gate; and
a backside contact located between the first vertical FET and the second vertical FET, wherein the backside contact extends through the gate, wherein the backside contact is connected to a backside surface of the lateral extending contact, wherein the backside contact has a first critical dimension located at the backside surface of the backside contact, wherein the backside contact has a second critical dimension located at the backside surface of the lateral extending contact, wherein the first critical dimension is greater than the second critical dimension.

9. The microelectronic structure of claim 8, wherein the first vertical FET further includes a first bottom source/drain, and the second vertical FET includes a second bottom source/drain.

10. The microelectronic structure of claim 9, wherein the first top source/drain, the first fin, and the first bottom source/drain combine to have a first combined vertical dimension.

11. The microelectronic structure of claim 10, wherein the backside contact has a backside vertical dimension, wherein the backside vertical dimension is greater than the first combined vertical dimension.

12. The microelectronic structure of claim 11, further comprises:
a first connecting via located on the backside surface of the first bottom source/drain;
a second connecting via located on the backside surface of the second bottom source/drain;
a first metal line connected to the first connecting via; and
a second metal line connected to the second connecting via.

13. The microelectronic structure of claim 5, wherein the first top source/drain, the first fin, the first bottom source/drain, the first connecting via, and the first metal line combine to have a second combined vertical dimension.

14. The microelectronic structure of claim 13, wherein the second combined vertical dimension is greater than the backside vertical dimension.

15. The microelectronic structure of claim 14, further comprising:
a connector located on the backside surface of the backside contact, wherein the connector is located between the first metal line and the second metal line.

16. The microelectronic structure of claim 15, wherein the connector has a vertical dimension, wherein the backside vertical dimension and the vertical dimension of the connector form a combined vertical dimension.

17. The microelectronic structure of claim 16, wherein the combined vertical dimension of the connector and the backside contact is greater than the second combined vertical dimension.

18. A method comprising:
forming a first vertical field-effect-transistor (FET) and a second vertical FET, wherein the first vertical FET is adjacent to the second vertical FET, wherein the first vertical FET includes a top source/drain;
forming a lateral extending contact that is located on top of the top source/drain, wherein the lateral extending contact extends towards the second vertical FET; and
forming a backside contact located between the first vertical FET and the second vertical FET, wherein the backside contact is connected to a backside surface of the lateral extending contact, wherein the backside contact has a first critical dimension located at the backside surface of the backside contact, wherein the backside contact has a second critical dimension located at the backside surface of the lateral extending contact, wherein the first critical dimension is greater than the second critical dimension.

19. The method of claim 18, wherein the first vertical FET further includes a bottom source/drain, and a vertical fin, wherein the top source/drain, the vertical fin, and the bottom source/drain combine to have a first combined vertical dimension.

20. The method of claim 19, wherein the backside contact has a backside vertical dimension, wherein the backside vertical dimension is greater than the first combined vertical dimension.
